(19) United States
(12) Patent Application Publication
(10) Pub. No.: US 2015/0027758 A1
(43) Pub. Date: Jan. 29, 2015

(54) MULTILAYER WIRING SUBSTRATE AND MANUFACTURING METHOD THEREFOR

(71) Applicant: NGK SPARK PLUG CO., LTD., Nagoya, Aichi (JP)

(72) Inventor: Shinnosuke Maeda, Phoenix, AZ (US)

(21) Appl. No.: 14/376,699

(22) PCT Filed: Mar. 20, 2013
(86) PCT No.: PCT/JP2013/001884

§ 371 Date: Aug. 5, 2014

(30) Foreign Application Priority Data
Apr. 26, 2012 (JP) 2012-101908

(51) Int. Cl. H05K 1/02; H05K 1/03; H05K 1/11

(52) U.S. Cl. CPC H05K 1/0298; H05K 1/115; H05K 1/0366; H05K 2201/029; H05K 2201/09563
USPC 174/255

(57) ABSTRACT

To provide a multilayer wiring substrate which can reliably prevent removal of a via conductor and which exhibits excellent connection reliability. A multilayer wiring substrate 10 has a multilayer build-up structure in which a plurality of resin insulation layers 33 and a plurality of conductor layers 42 are alternately stacked. Each of the resin insulation layers 33 formed of a resin insulation material 50 contains therein a glass cloth 51. The resin insulation material 50 of the resin insulation layer 33 has a via hole 43, and the glass cloth 51 has an aperture 52 at a position corresponding to the via hole 43. A portion of the glass cloth 51 corresponding to a opening edge of the aperture 52 protrudes inwardly from the inner wall of the via hole 43, and enters a side portion of the via conductor 44. Tip ends of glass fiber filaments 57 protruding from the inner wall 54 of the via hole 43 are bonded together through melting to form a weld portion 58.

### TECHNICAL FIELD

The present invention relates to a multilayer wiring substrate having a multilayer build-up structure in which a plurality of resin insulation layers and a plurality of conductor layers are alternately stacked; and to a method for producing the multilayer wiring substrate.

### BACKGROUND ART

In recent years, with the progress of miniaturization of electrical devices, electronic devices, and the like, demand has arisen for reducing the size of, for example, a multilayer wiring substrate or the like which is mounted on such a device, and also for increasing the packing density of the wiring substrate. Practically used multilayer wiring substrates include a wiring substrate produced through the so-called build-up process, in which a plurality of resin insulation layers and a plurality of conductor layers are alternately stacked together (see, for example, Patent Document 1). In the multilayer wiring substrate described in Patent Document 1, a conductor layer formed on the lower surface of a resin insulation layer is connected to a conductor layer formed on the upper surface of the resin insulation layer by the mediation of via conductors formed in the resin insulation layer.

More specifically, in the multilayer wiring substrate described in Patent Document 1, each resin insulation layer is formed of a resin insulation material containing a glass cloth. In the resin insulation layer, the glass cloth protrudes from the inner wall of a via hole provided in the layer so as to penetrate in a thickness direction, and the glass cloth enters a side portion of a via conductor formed in the via hole.

Also, the wiring substrate described in Patent Document 2 includes a resin insulation layer containing a glass cloth. In the resin insulation layer, fiber filaments of the glass cloth protruding from a side wall of a via hole are bonded together, and the thus-bonded portion is buried in a via conductor.

### PRIOR ART DOCUMENT

### Patent Document

Patent Document 1: Japanese Patent Application Laid-Open (kokai) No. 2009-246358
Patent Document 2: Japanese Patent Application Laid-Open (kokai) No. 2007-227809

### SUMMARY OF THE INVENTION

### Problems to be Solved by the Invention

In the multilayer wiring substrate described in Patent Document 1, tip ends of glass cloth fiber filaments protruding from the inner wall of each via hole are not bonded together, and the tip ends of the glass cloth fiber filaments enter a side portion of the via conductor in a lateral direction (i.e., in a radial direction of the via conductor). Also, adhesion between the glass cloth fiber filaments and the via conductor is low. Therefore, when a relatively large stress is applied to the via conductor, since the via conductor may fail to be held by means of protruding portions of the glass cloth fiber filaments, there is a concern that the via conductor formed in the via hole may be removed therefrom; i.e., a problem may occur in terms of removal of the via conductor. Thus, demand has arisen for a further improved multilayer wiring substrate exhibiting enhanced connection reliability.

Meanwhile, in the wiring substrate described in Patent Document 2, glass cloth fiber filaments protruding from the inner wall of the via hole are bonded together to form a U-shaped portion. The U-shaped bonded portion functions to prevent the glass cloth fiber filaments from entering the via hole. Thus, in the wiring substrate described in Patent Document 2, since the U-shaped bonded portion only slightly protrudes from the inner wall of the via hole, this portion may fail to sufficiently exhibit the effect of fixing the via conductor in the via hole.

In view of the foregoing, an object of the present invention is to provide a multilayer wiring substrate which can reliably prevent removal of a via conductor and which exhibits excellent connection reliability. Another object of the present invention is to provide a multilayer wiring substrate production method suitable for producing the multilayer wiring substrate.

### Means for Solving the Problems

One means for solving the aforementioned problems (means 1) is a multilayer wiring substrate which has a multilayer build-up structure including a plurality of resin insulation layers and a plurality of conductor layers, the resin insulation layers and the conductor layers being alternately stacked, and in which at least one of the resin insulation layers contains an inorganic fiber layer in an inner layer portion of a insulation material; the resin insulation material of the resin insulation layer has a via hole; the inorganic fiber layer has an aperture at a position corresponding to the via hole; and a via conductor that electrically connects the conductor layers is formed in the via hole and the aperture, the multilayer wiring substrate being characterized in that a portion of the inorganic fiber layer defining the aperture protrudes inwardly from the inner wall of the via hole lying adjacent to the inorganic fiber layer; and tip ends of a plurality of inorganic fiber filaments of the inorganic fiber layer protruding inwardly from the inner wall of the via hole are bonded together through melting to form a wall-like weld portion extending along the inner wall of the via hole.

The diameter of the aperture may be the smallest at an inner-layer-side opening portion of an inner side surface of the weld portion. The mean diameter of the apertures may be smaller than the size of the via hole at an outer-layer-side end thereof, and smaller than that at an inner-layer-side end thereof. The mean diameter of the apertures may be ⅓ or more the diameter of a largest-size portion of the via hole. With this configuration, a portion of the inorganic fiber layer defining the aperture can reliably enter a side portion of the via conductor, and removal of the via conductor can be reliably prevented.

The diameter of the via hole at the outer-layer-side thereof may be larger than that at the inner-layer-side thereof. In this case, the via conductor can be reliably formed in the via hole through the outer-layer-side end during plating.

The inner side surface of the weld portion may be tapered such that the diameter of the aperture gradually decreases from an outer-layer-side opening portion toward the inner-layer-side opening portion. When the weld portion is formed in this manner, the weld portion can be reliably buried in the via conductor.

The length of the weld portion, as measured in a circumferential direction of the via hole, is 5% or more the inner circumferential length of the via hole at a position lying adjacent to the inorganic fiber layer. In this case, the area of the weld portion can be sufficiently provided, and removal of the via conductor can be reliably prevented.

The mean fiber diameter of inorganic fiber filaments forming the inorganic fiber layer may be 5.0 μm or less. When such thin inorganic fiber filaments are employed, the inorganic fiber filaments are readily melted by heat from laser drilling, and a relatively large weld portion can be formed.

The via conductor may be a filled via conductor charged in the via hole and the aperture. Alternatively, the via conductor may be a conformal via conductor which is formed so as to extend along the inner wall of the via hole and to be dented inwardly.

The resin insulation layer may contain, in addition to the inorganic resin layer, another inorganic material. The thermal expansion coefficient of the resin insulation layer can be reduced through incorporation of such an additional inorganic material. No particular limitation is imposed on the form of an inorganic material incorporated into the resin insulation layer. The resin insulation layer may be formed so as to contain, for example, a silica filler (i.e., a granular inorganic material). Specific examples of the inorganic fiber layer contained in the resin insulation layer include glass cloth. The resin insulation layer may be formed so as to contain only the inorganic fiber layer without incorporation of a granular inorganic material. No particular limitation is imposed on the thickness of the resin insulation layer, and, for example, an insulation layer having a thickness of 50 μm or less may be employed. When a resin insulation layer having a thickness of 50 μm or less is employed, the thickness of the multilayer wiring substrate can be reduced.

When a glass cloth is employed as the inorganic fiber layer, the glass cloth may be located at a center portion of the resin insulation layer in a thickness direction. In this case, the glass cloth is not exposed through the surface of the resin insulation layer, and the glass cloth can be reliably provided inside the resin insulation layer. Since the glass cloth protrudes from a center portion of the inner wall of the via hole, removal of the via conductor can be reliably prevented.

The resin insulation material forming the resin insulation layer may be appropriately determined in consideration of, for example, insulation property, heat resistance, and moisture resistance. Examples of preferred resin insulation materials include thermosetting resins such as epoxy resin, phenolic resin, urethane resin, silicone resin, and polyimide resin; and thermoplastic resins such as polycarbonate resin, acrylic resin, polyacetal resin, and polypropylene resin.

Another means for solving the aforementioned problems (means 2) is a method for producing the multilayer wiring substrate as described in means 1, characterized in that the method comprises an insulation layer provision step of providing, on a conductor layer, a resin insulation layer made of a resin insulation material and containing a glass cloth serving as an inorganic fiber layer; a via hole provision step of subjecting the resin insulation layer to laser drilling employing a carbon dioxide gas laser, to thereby provide a via hole in the resin insulation material, to provide an aperture in the glass cloth, and to form a weld portion through melting and bonding, by means of heat generated during laser drilling, of tip ends of a plurality of glass fiber filaments of the glass cloth protruding from the inner wall of the via hole; and a via conductor formation step of forming, through plating, a via conductor in the via hole and the aperture.

### Effects of the Invention

According to the invention described in means 1, since a portion of the inorganic fiber layer defining the aperture protrudes inwardly from the inner wall of the via hole, the protruding portion of the inorganic fiber layer can enter a side portion of the via conductor. Also, tip ends of a plurality of inorganic fiber filaments of the inorganic fiber layer protruding inwardly from the inner wall of the via hole are bonded together through melting to form a wall-like weld portion. This wall-like weld portion extends along the inner wall of the via hole. With this configuration, since the via conductor can be held by means of the weld portion having a relatively large area, removal of the via conductor from the via hole can be suppressed as compared with the cases of conventional techniques, whereby the via conductor exhibits enhanced connection reliability.

According to the invention described in means 2, the via hole provision step is carried out after the insulation layer provision step of providing, on the conductor layer, the resin insulation layer containing a glass cloth. In the via hole provision step, the resin insulation layer is subjected to laser drilling employing a carbon dioxide gas laser, to thereby provide a via hole in the resin insulation material, and also to provide an aperture in the glass cloth. Since the resin insulation material exhibits higher absorption rate to carbon dioxide gas laser energy, as compared with the glass cloth, the resin insulation material around the glass cloth is removed, and thus the glass cloth protrudes from the inner wall of the via hole. In addition, a weld portion is formed through melting and bonding of tip ends of a plurality of glass fiber filaments by means of heat generated during laser drilling. Thereafter, plating is carried out in the via conductor formation step, to thereby form a via conductor in the via hole and the aperture. Removal of the via conductor can be reliably prevented through formation of the weld portion, and the thus-produced multilayer wiring substrate exhibits excellent connection reliability.

### BRIEF DESCRIPTION OF THE DRAWINGS

FIG. 1 is a schematic cross-sectional view of the configuration of a multilayer wiring substrate according to an embodiment.

FIG. 2 is an enlarged cross-sectional view of a via hole and a via conductor formed in a resin insulation layer.

FIG. 3 is a schematic perspective view of the via hole and a weld portion formed in the resin insulation layer.

FIG. 4 shows a core substrate formation step of a multilayer wiring substrate production method.

FIG. 5 shows an insulation layer provision step of the multilayer wiring substrate production method.

FIG. 6 shows a via hole formation step of the multilayer wiring substrate production method.

FIG. 7 shows a via conductor formation step of the multilayer wiring substrate production method.

FIG. 8 shows a build-up step of the multilayer wiring substrate production method.

FIG. 9 shows an SEM photograph of a via hole and a via conductor according to the embodiment.

FIG. 10 is a cross-sectional view of a via hole and a via conductor according to another embodiment.

### MODES FOR CARRYING OUT THE INVENTION

One specific embodiment of the multilayer wiring substrate of the present invention will next be described in detail with reference to the drawings.

As shown in FIG. 1, a multilayer wiring substrate 10 according to the present embodiment includes a core substrate 11, a first build-up layer 31 formed on a core front surface (top surface in FIG. 1) of the core substrate 11, and a second build-up layer 32 formed on a core back surface 13 (bottom surface in FIG. 1) of the core substrate 11.

The core substrate 11 is formed of, for example, a resin insulating material (glass epoxy material) prepared by impregnating a glass cloth (serving as a reinforcing material) with an epoxy resin. The core substrate 11 has a plurality of apertures 15 penetrating in a thickness direction, and an aperture conductor 16 is provided in each aperture 15. The aperture conductor 16 connects the core front surface 12 side of the core substrate 11 with the core back surface 13 side thereof. Each aperture conductor 16 is filled with a blocking body 17 made of, for example, an epoxy resin. Patterned copper conductor layers 41 are formed on the core front surface 12 of the core substrate 11 and on the core back surface 13 thereof, and each conductor layer 41 is electrically connected to the aperture conductor 16.

The first build-up layer 31 formed on the core front surface 12 of the core substrate 11 has a build-up structure including a plurality of resin insulation layers 33 and 35 mainly formed of a thermosetting resin (epoxy resin as a resin insulation material), and a plurality of copper conductor layers 42, wherein the resin insulation layers 33 and 35 and the conductor layers 42 are alternately stacked. A plurality of terminal pads 45 are formed on the resin insulation layer 35 in an array pattern. Almost the entire top surface of the resin insulation layer 35 is covered with a solder resist film 37. Openings 46 through which the terminal pads 45 are respectively exposed are provided at specific positions of the solder resist film 37. The terminal pads 45 exposed through the openings 46 are electrically connected to connection terminals of a semiconductor chip by the mediation of non-illustrated solder bumps. The resin insulation layer 33 has via holes 43 and via conductors 44 formed therein. Similarly, the resin insulation layer 35 has via holes 43 and via conductors 44 formed therein. The via conductors 44 electrically connect the conductor layers 41 and 42 and the terminal pads 45.

The second build-up layer 32 formed on the core back surface 13 of the core substrate 11 has almost the same structure as the aforementioned first build-up layer 31. Specifically, the second build-up layer 32 has a build-up structure including a plurality of resin insulation layers 34 and 36 mainly formed of a thermosetting resin (epoxy resin as a resin insulation material), and a plurality of conductor layers 42, wherein the resin insulation layers 34 and 36 and the conductor layers 42 are alternately stacked. The resin insulation layer 34 has via holes 43 and via conductors 44 formed therein. Similarly, the resin insulation layer 36 has via holes 43 and via conductors 44 formed therein. A plurality of BGA pads 48 are formed on the bottom surface of the resin insulation layer 36 in an array pattern. Almost the entire bottom surface of the resin insulation layer 36 is covered with a solder resist film 38. Openings 49 through which the BGA pads 48 are respectively exposed are provided at specific positions of the solder resist film 38. The BGA pads 48 exposed through the openings 49 are electrically connected to a motherboard (external board) by the mediation of non-illustrated solder bumps.

Each of the resin insulation layers 33 to 36 according to the present embodiment contains a glass cloth 51 serving as an inorganic fiber layer in an inner layer portion of a resin insulation material 50. More specifically, each of the resin insulation layers 33 to 36 is formed of a build-up material containing the glass cloth 51 and a silica filler (i.e., a granular inorganic material). Each of the resin insulation layers 33 to 36 has a thickness of about 40 and the glass cloth 51 has a thickness of about 15 Each of the resin insulation layers 33 to 36 contains therein the glass cloth 51 at generally a center portion in a thickness direction.

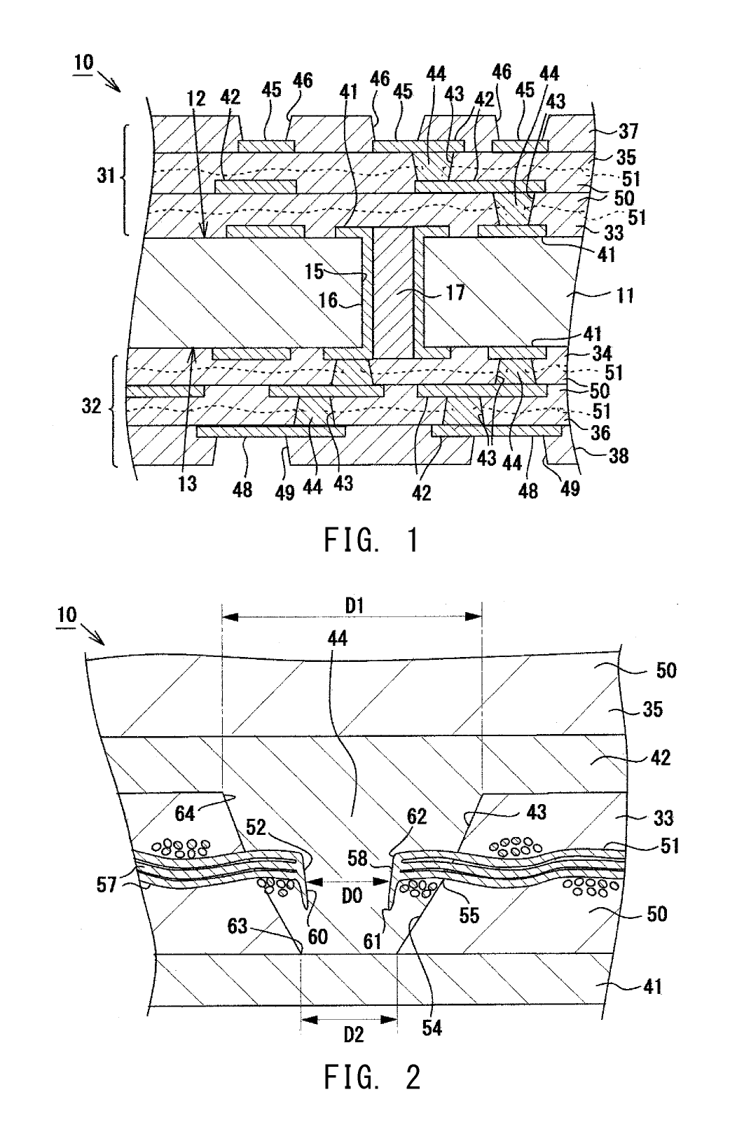

As shown in FIG. 2, the resin insulation material 50 of the resin insulation layer 33 has via holes 43, and the glass cloth 51 has apertures 52 at a position corresponding to the via holes 43. The via conductor 44, which electrically connects the conductor layers 41 and 42, is formed in each via hole 43 and each aperture 52. In the present embodiment, the via conductor 44 is a filled via conductor charged in each via hole 43 and each aperture 52, and the via holes 43 and the via conductors 44 are formed so as to assume an inverse truncated conical shape. The inner wall 54 of the via hole 43 has an step 55 at a depth position corresponding to the glass cloth 51.

A portion of the glass cloth 51 defining the aperture 52 protrudes inwardly from the inner wall of the via hole 43 lying adjacent to the glass cloth 51, and enters a side portion of the via conductor 44. Tip ends of a plurality of glass fiber filaments 57 of the glass cloth 51 protruding inwardly from the inner wall 54 of the via hole 43 are bonded together through melting to form a weld portion 58. In the present embodiment, the glass fiber filaments 57 forming the glass cloth 51 have a mean fiber diameter of 5.0 μm or less.

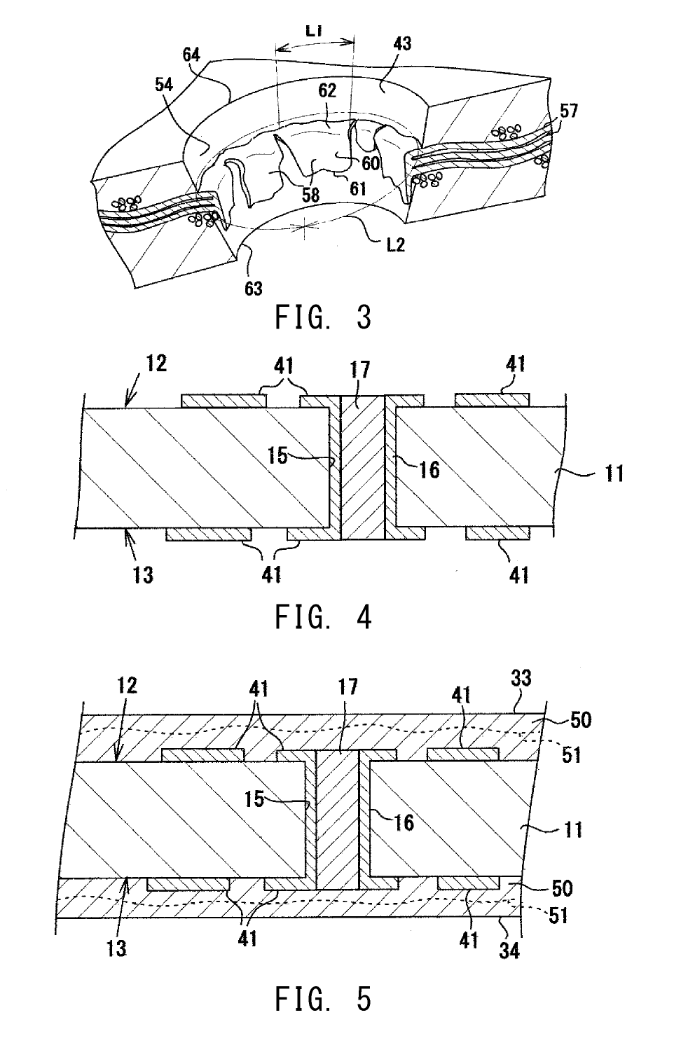

As shown in FIGS. 2 and 3, the wall-like weld portions 58 are formed through welding of a plurality of glass fiber filaments 57 extending in a lateral direction and a vertical direction (i.e., in a thickness direction of the insulation layer). The wall-like weld portions 58 extend along the inner wall 54 of the via hole 43. FIG. 3 is a schematic perspective cross-sectional view of the via hole 43 taken along a line including the axis thereof, with the via conductor 44 being omitted.

The inner side surface 60 of the weld portion 58 is tapered such that the diameter of the aperture gradually decreases from an outer-layer-side opening portion 62 toward an inner-layer-side opening portion 61. That is, the diameter of the aperture 52 is the smallest at the inner-layer-side opening portion 61 of the inner side surface 60 of the weld portion 58. Specifically, the mean diameter D0 of the aperture 52 is about 25 μm, and the diameter of the aperture 52 at the inner-layer-side opening portion 61 is about 20 μm. The diameter of the via hole 43 increases from an inner-layer-side opening portion 63 toward an outer-layer-side opening portion 64, and is the largest at the outer-layer-side opening portion 64. That is, the diameter D1 of the via hole 43 at the outer-layer-side is larger than the diameter D2 thereof at the inner-layer-side. The diameter D1 of the via hole 43 at the outer-layer-side is about 70 μm, and the diameter D2 thereof at the inner-layer-side is about 30 μm. The mean diameter D0 of the aperture 52 is smaller than the diameter D1 of the via hole 43 at the outer-layer-side, and smaller than the diameter D2 of the via hole 43 at the inner-layer-side. The mean diameter D0 of the aperture 52 is ⅓ or more the largest diameter of the via hole 43 (at the outer-layer-side opening portion 64).

In the present embodiments, a plurality of weld portions 58 having different sizes are formed in a circumferential direction. The length L1 of the largest weld portion 58, as measured in a circumferential direction of the via hole 43, is 5% or more the inner circumferential length L2 of the via hole 43 at a position lying adjacent to the glass cloth 51.

Next will be described a method for producing the multilayer wiring substrate 10 according to the present embodiment.

Firstly, there is provided a copper-clad laminate prepared by attaching copper foils onto opposite surfaces of a glass epoxy substrate. Subsequently, apertures 15 penetrating the copper-clad laminate (including the front and back surfaces thereof) are provided at specific positions through drilling by means of a drill. Then, electroless copper plating and electrolytic copper plating are carried out on the inner walls of the apertures 15 of the copper-clad laminate, to thereby form an aperture conductor 16 in each aperture 15.

Thereafter, a hollow portion of each aperture conductor 16 is filled with an insulation resin material (epoxy resin), to thereby form a blocking body 17. Then, the copper foil of the copper-clad laminate and a copper plating layer formed on the copper foil are subjected to patterning through, for example, the subtractive process, to thereby produce, as shown in FIG. 4, a core substrate 11 having the aperture conductor 16 and conductor layers 41.

Subsequently, a build-up process is carried out, to thereby form a first build-up layer 31 on a core front surface 12 of the core substrate 11, and also form a second build-up layer 32 on a core back surface 13 of the core substrate 11.

Specifically, as shown in FIG. 5, sheet-like resin insulation layers 33 and 34, each being formed of a resin insulation material 50 containing a glass cloth 51, are respectively provided on and attached to the core front surface 12 and the core back surface 13 of the core substrate 11 having thereon the conductor layers 41 (insulation layer provision step).

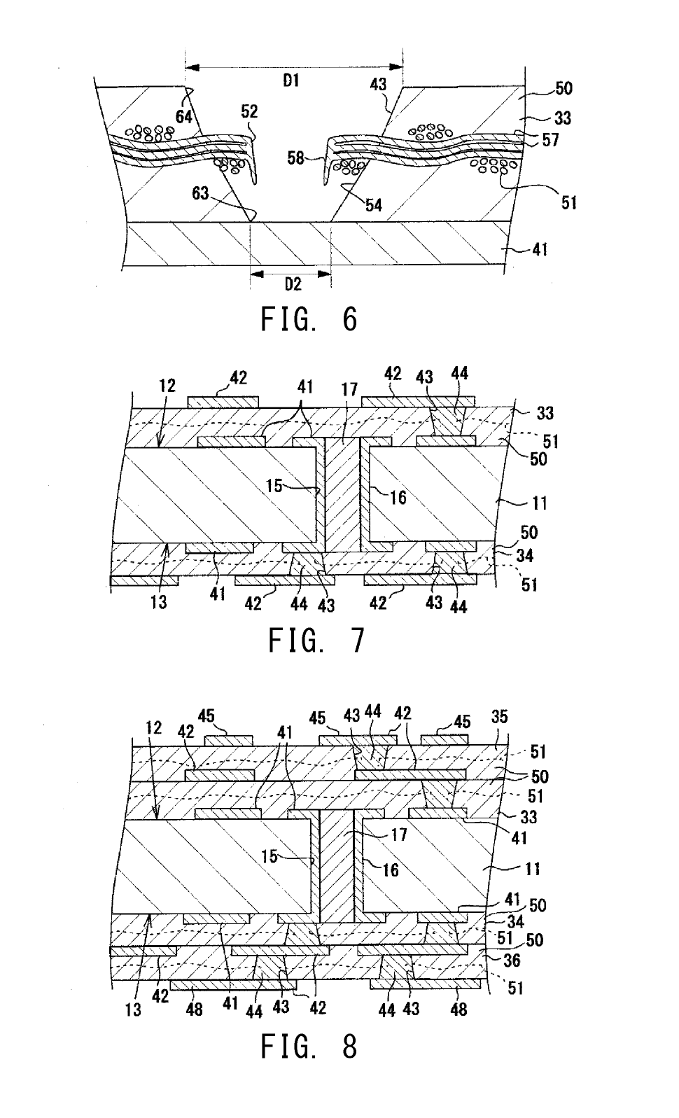

Thereafter, the resin insulation layers 33 and 34 are subjected to laser drilling by means of a carbon dioxide gas laser (CO₂ laser), to thereby provide via holes 43 at specific positions of the resin insulation layers 33 and 34, respectively, and to provide apertures 52 in the glass cloth (via hole provision step). Since the resin insulation material 50 exhibits higher absorption rate to carbon dioxide gas laser energy, as compared with the glass cloth 51, a portion of the glass cloth 51 protrudes from the inner wall 54 of the via hole 43. In this case, tip ends of a plurality of glass fiber filaments 57 of the glass cloth 51 protruding from the inner wall 54 of the via hole 43 are melted and bonded together by means of heat generated during laser drilling, to thereby form weld portions 58 (see FIG. 6). In this laser drilling process, a laser beam is applied to the outer-layer-side opening portion 64 from above. Therefore, the diameter D1 of the via hole 43 at the outer-layer-side opening portion 64 becomes larger than the diameter D2 thereof at the inner-layer-side opening portion 63.

Subsequently, by use of an etchant such as a potassium permanganate solution, a desmear step is carried out for removing smears from the via hole 43. In the desmear step, in place of treatment by use of an etchant, plasma asking by means of, for example, O₂ plasma may be performed.

After completion of the desmear step, electroless copper plating and electrolytic copper plating are carried out through a conventionally known technique, to thereby form a via conductor 44 in each via hole 43 (via conductor formation step). In addition, etching is carried out through a conventionally known technique (e.g., the semi-additive process), to thereby form conductor layers 42 in a specific pattern on the resin insulation layers 33 and 34 (see FIG. 7).

Other resin insulation layers 35 and 36 and conductor layers 42 are formed on the resin insulation layers 33 and 34 in a manner similar to that employed in formation of the aforementioned resin insulation layers 33 and 34 and conductor layers 42. The conductor layers 42 formed on the resin insulation layer 35 serve as terminal pads 45, and the conductor layers 42 formed on the resin insulation layer 36 serve as BGA pads 48 (see FIG. 8).

Next, a photosensitive epoxy resin is applied onto the resin insulation layers 35 and 36, and then the resin is cured, to thereby form solder resist films 37 and 38. Thereafter, specific masks are placed on the solder resist films 37 and 38, and light exposure and development are carried out, to thereby provide openings 46 and 49 in the solder resist films 37 and 38, respectively, in a specific pattern. Through the above-described steps, the multilayer wiring substrate 10 shown in FIG. 1 is produced.

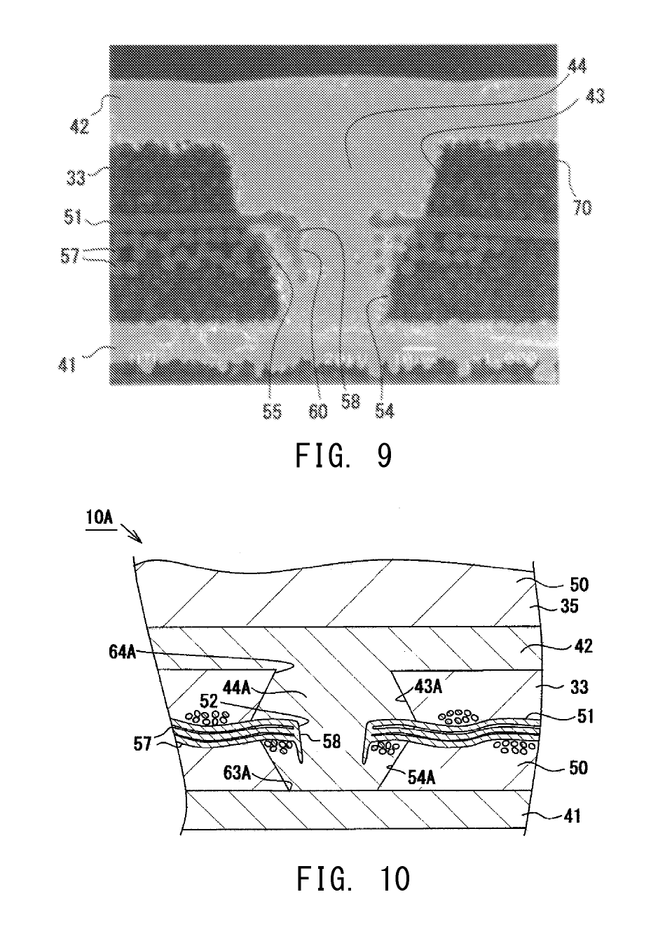

The present inventors cut the above-described multilayer wiring substrate 10 in a thickness direction along a line including the axis of the via conductor 44, and observed a cut surface of the via conductor 44 under an electron microscope (SEM). FIG. 9 shows an SEM photograph 70 of the cut surface of the via conductor 44.

As shown in FIG. 9, in the via hole 43 having an inverse truncated conical shape, the protruding glass cloth 51 enters a side portion of the via conductor 44. Also, the weld portions 58 are formed through melting and bonding of tip ends of glass fiber filaments 57 of the glass cloth 51 protruding inwardly from the inner wall 54 of the via hole 43. The weld portions 58 were formed so as to sag downward, and the inner side surfaces 60 thereof assumed a tapered surface. In addition, it was found that the inner wall 54 of the via hole 43 has a step 55 at a position corresponding to the protruding glass cloth 51, and the inclination angle slightly changes at the step 55. Also, it was found that the via hole 43 is completely filled with the via conductor 44; i.e., adhesion between the via conductor 44 and the via hole 43 is sufficiently provided.

Therefore, the present embodiment can yield the following effects.

(1) In the multilayer wiring substrate 10 of the present embodiment, since a portion of the glass cloth 51 defining the aperture 52 protrudes inwardly from the inner wall 54 of the via hole 43, the protruding portion of the glass cloth 51 can enter a side portion of the via conductor 44. Also, tip ends of a plurality of glass fiber filaments 57 of the glass cloth 51 protruding inwardly from the inner wall 54 of the via hole 43 are bonded together through melting to form the wall-like weld portions 58. The wall-like weld portions 58 extend along the inner wall 54 of the via hole 43. With this configuration, since the via conductor 44 can be held by means of the weld portions 58 having a relatively large area, removal of the via conductor 44 from the via hole 43 is suppressed, whereby the via conductor 44 exhibits enhanced connection reliability.

(2) In the multilayer wiring substrate 10 of the present embodiment, the inner side surface 60 of each weld portion 58 is tapered such that the diameter of the aperture gradually decreases from the outer-layer-side opening portion 62 toward the inner-layer-side opening portion 61, and the diameter of the aperture 52 is the smallest at the inner-layer-side opening portion 61 of the inner side surface 60 of the weld portion 58. With this configuration, the weld portions 58 formed of the glass fiber filaments 57 can reliably enter a side portion of the via conductor 44, and removal of the via conductor can be reliably prevented.

(3) In the multilayer wiring substrate 10 of the present embodiment, the length L1 of a weld portion 58, as measured in a circumferential direction of the via hole 43, is 5% or more the inner circumferential length L2 of the via hole 43 at a position lying adjacent to the glass cloth 51. In this case, the area of the weld portion 58 can be sufficiently provided, and removal of the via conductor can be reliably prevented.

(4) The present embodiment employs the glass cloth 51 which is formed of glass fiber filaments 57 having a mean diameter of 5.0 μm or less. When such thin glass fiber filaments 57 are employed, the glass fiber filaments 57 are readily melted by heat obtained from laser drilling, and relatively large weld portions 58 can be formed.

(5) In the multilayer wiring substrate 10 of the present embodiment, the mean diameter D0 of the apertures 52 provided in the glass cloth 51 is smaller than the diameter D1 of the via hole 43 at the outer-layer-side, and smaller than the diameter D2 thereof at the inner-layer-side, and the mean diameter D0 is ⅓ or more the diameter D1 at the outer-layer-side (i.e., the largest diameter of the via hole 43). In this case, a portion of the glass cloth defining the aperture 52 can reliably enter a side portion of the via conductor 44. In addition, the diameter D1 of the via hole 43 at the outer-layer-side is larger than the diameter D2 thereof at the inner-layer-side. When the diameter D1 at the outer-layer-side is larger as described above, the filled via conductor 44 can be reliably formed in the via hole 43 through the outer-layer-side opening portion 64 during plating.

(6) In the multilayer wiring substrate 10 of the present embodiment, each of the resin insulation layers 33 to 36 contains therein the glass cloth 51 at generally a center portion in a thickness direction. In this case, the glass cloth 51 is not exposed through the surface of each of the resin insulation layers 33 to 36, and the glass cloth 51 can be reliably provided inside each of the resin insulation layers 33 to 36. Since the glass cloth 51 protrudes from a center portion of the inner wall 54 of the via hole 43, removal of the via conductor can be reliably prevented. In addition, the strength of each of the resin insulation layers 33 to 36 can be sufficiently attained through incorporation of the glass cloth 51.

The embodiment of the present invention may be modified as follows.

In the multilayer wiring substrate 10 of the aforementioned embodiment, each of the resin insulation layers 33 to 36 contains the glass cloth 51, the glass cloth 51 protrudes from the inner wall 54 of each via hole 43 provided in each of the insulation layers 33 to 36, and the weld portions 58 are formed at the tip ends of glass fiber filaments 57. However, the present invention is not limited thereto. Specifically, at least one of the resin insulation layers 33 to 36 forming the multilayer wiring substrate 10 may contain the glass cloth 51, and the weld portion 58 of the glass cloth 51 may be formed in at least one via hole 43 provided in the glass-cloth-containing resin insulation layer.

In the multilayer wiring substrate 10 of the aforementioned embodiment, the via holes 43 and the via conductors 44 formed in each of the resin insulation layers 33 to 36 have an inverse truncated conical shape. However, the shape of the via holes 43 and the via conductors 44 is not limited thereto. As shown in FIG. 10 (i.e., a multilayer wiring substrate 10A), via holes 43A and via conductors 44A, each having a generally hexagonal (abacus-bead) cross-section, may be formed in each of the resin insulation layers 33 to 36. Similar to the case of the multilayer wiring substrate 10, in the multilayer wiring substrate 10A, a portion of the glass cloth 51 defining of the aperture 52 protrudes inwardly from the inner wall 54A of the via hole 43A and enters a side portion of the via conductor 44A. Also, tip ends of a plurality of glass fiber filaments 57 of the glass cloth 51 protruding inwardly from the inner wall of the via hole 43A are bonded together through melting to form the weld portions 58.

The resin insulation layers 33 to 36 are formed of a build-up material containing only the glass cloth 51 (i.e., containing no silica filler as a granular inorganic material). In this case, the resin insulation material 50 of each of the resin insulation layers 33 to 36 can be readily processed during laser drilling. Thus, heat generated during provision of the aperture 52 in the glass cloth 51 transfers through the glass cloth 51 in an in-plane direction thereof, whereby the resin insulation material 50 around the perimeter of the aperture 52 is much more fired out. Therefore, each via hole 43A provided in each of the resin insulation layers 33 to 36 has the largest diameter at a position of the inner wall 54A lying adjacent to the glass cloth 51. The mean diameter of the apertures 52 provided in the glass cloth 51 is smaller than the diameter of the via hole 43 at an inner-layer-side opening portion 63A, and smaller than the diameter thereof at an outer-layer-side opening portion 64A. In addition, the diameter of the via hole 43 at the outer-layer-side opening portion 64A is larger than that at the inner-layer-side opening portion 63A. Also in the multilayer wiring substrate 10A, since the weld portions 58 of the glass cloth 51 are formed in each the via hole 43A, removal of the via conductor 44A from the via hole 43A is prevented, and the via conductor 44A exhibits enhanced connection reliability. Furthermore, since the via holes 43A have a shape such that it tapers toward the inner-layer-side opening portion 63A and the outer-layer-side opening portion 64A, removal of the via conductors can be reliably prevented.

In the aforementioned multilayer wiring substrate 10 or 10A, the via conductors 44 or 44A are a filled via conductor; i.e., the via holes 43 or 43A and the apertures 52 are filled with the via conductor. However, the form of the corresponding via conductors is not limited thereto. Specifically, the multilayer wiring substrate may be produced by replacing the via conductors 44 or 44A with conformal via conductors each of which is formed so as to extend along the inner wall 54 or 54A of the via hole 43 or 43A and to be dented inwardly.

Although the aforementioned embodiment of the present invention is directed to the multilayer wiring substrate 10 including the core substrate 11, the present invention may be applied to a wiring substrate which does not include the core substrate 11; i.e., a coreless wiring substrate.

The package form of the multilayer wiring substrate 10 of the aforementioned embodiment is not limited only to a BGA (ball grid array), and the present invention may be applied to a wiring substrate for, for example, a PGA (pin grid array) or an LGA (land grid array).

Next will be given technical ideas that can be understood from the above-described embodiments, other than technical ideas described in the appended claims.

(1) The multilayer wiring substrate described in means 1, wherein the resin insulation layer is formed so as not to contain a granular inorganic material.

(2) The multilayer wiring substrate described in means 1, wherein the glass cloth serving as an inorganic fiber layer is located at a center portion of the resin insulation layer in a thickness direction.

(3) The multilayer wiring substrate described in means 1, wherein the resin insulation layer has a thickness of 50 or less.

(4) The multilayer wiring substrate described in means 1, wherein the mean diameter of the aperture is ⅓ or more the diameter of a largest-diameter portion of the via hole.

(5) The multilayer wiring substrate described in means 1, wherein the mean diameter of the aperture is smaller than the diameter of the via hole at an outer-layer-side thereof, and smaller than that at an inner-layer-side thereof.

(6) The multilayer wiring substrate described in means 1, wherein the diameter of the via hole at an outer-layer-side thereof is larger than that at an inner-layer-side thereof.

### DESCRIPTION OF REFERENCE NUMERALS

10, 10A: multilayer wiring substrate
33 to 36: resin insulation layer
42: conductor layer
43, 43A: via hole
44, 44A: via conductor
50: resin insulation material
51: glass cloth as inorganic fiber layer
52: aperture
54, 54A: inner wall of via hole
57: glass fiber filament as inorganic fiber filament
58: weld portion
60: inner side surface of weld portion
61: inner-layer-side opening portion of weld portion
62: outer-layer-side opening portion of weld portion
63, 63A: inner-layer-side opening portion of via hole
64, 64A: outer-layer-side opening portion of via hole
L1: length of weld portion
L2: inner circumferential length of via hole

What is claimed is:

1. A multilayer wiring substrate which has a multilayer build-up structure including a plurality of resin insulation layers and a plurality of conductor layers, the resin insulation layers and the conductor layers being alternately stacked, and in which at least one of the resin insulation layers contains an inorganic fiber layer in an inner layer portion of a resin insulation material; the resin insulation material of the resin insulation layer has a via hole; the inorganic fiber layer has an aperture at a position corresponding to the via hole; and a via conductor that electrically connects the conductor layers is formed in the via hole and the aperture, the multilayer wiring substrate being characterized in that:
a portion of the inorganic fiber layer defining the aperture protrudes inwardly from the inner wall of the via hole lying adjacent to the inorganic fiber layer; and
tip ends of a plurality of inorganic fiber filaments of the inorganic fiber layer protruding inwardly from the inner wall of the via hole are bonded together through melting to form a wall-like weld portion extending along the inner wall of the via hole.

2. A multilayer wiring substrate according to claim 1, wherein the diameter of the aperture is the smallest at an inner-layer-side opening portion of an inner side surface of the weld portion.

3. A multilayer wiring substrate according to claim 1, wherein the inner side surface of the weld portion is tapered such that the diameter of the aperture gradually decreases from an outer-layer-side opening portion toward the inner-layer-side opening portion.

4. A multilayer wiring substrate according to claim 1, wherein the length of the weld portion, as measured in a circumferential direction of the via hole, is 5% or more the inner circumferential length of the via hole at a position lying adjacent to the inorganic fiber layer.

5. A multilayer wiring substrate according to claim 1, wherein the mean diameter of inorganic fiber filaments forming the inorganic fiber layer is 5.0 μm or less.

6. A multilayer wiring substrate according to claim 1, wherein the via conductor is a filled via conductor charged in the via hole and the aperture.

7. A method for producing the multilayer wiring substrate as recited in claim 1, characterized in that the method comprises:
an insulation layer provision step of providing, on a conductor layer, a resin insulation layer made of a resin insulation material and containing a glass cloth serving as an inorganic fiber layer;
a via hole provision step of subjecting the resin insulation layer to laser drilling employing a carbon dioxide gas laser, to thereby provide a via hole in the resin insulation material, to provide an aperture in the glass cloth, and to form a weld portion through melting and bonding, by means of heat generated during laser drilling, of tip ends of a plurality of glass fiber filaments of the glass cloth protruding from the inner wall of the via hole; and
a via conductor formation step of forming, through plating, a via conductor in the via hole and the aperture.
